(19) United States
(12) Patent Application Publication
(10) Pub. No.: US 2009/0230543 A1
(43) Pub. Date: Sep. 17, 2009

(54) Semiconductor package structure with heat sink

(76) Inventors: Ping Hsun Yu, Hsinchu (TW); Ching Wei Hung, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/081,145

(22) Filed: Apr. 11, 2008

(30) Foreign Application Priority Data
Mar. 11, 2008 (TW) 97108540

(51) Int. Cl. H01L 23/36

(52) U.S. Cl. 257/712; 257/E23.101

(57) ABSTRACT

A semiconductor package structure with a heat sink is disclosed herein. The semiconductor package structure includes a substrate having a chip mounting area and a plurality of through holes surrounding the chip mounting area; a chip set on the chip mounting area and electrically connected to the substrate; a heat sink covering the chip, wherein the heat sink has a plurality of support portions extending from the upper surface to the lower surface of the substrate via those through holes; and a molding compound covering the chip, a portion of the substrate and the heat sink. Those support portions of the heat sink are utilized to improve the heat dissipation efficiency and the warpage issue of the package.

### BACKGROUND OF THE INVENTION

1. Field of the Invention

The present invention relates to a semiconductor package structure with a heat sink, particularly to a semiconductor package structure with a heat sink that is capable of solving the warpage issue of the package.

2. Description of the Prior Art

IC (integrated circuit) packaging belongs to the back-end stage of semiconductor device fabrication and includes wafer sawing, die attaching, wire bonding, molding, marking, and packaging. The main purpose of IC packaging is to saw the IC on a wafer processed with front-end processes into dies, attach the dies, bond the dies with wires, and package the IC. Recently, due to the highly integrated semiconductor chips, the accompanied heat generated increases accordingly. However, the trend of getting package structures thinner and smaller results in heat congested in the small-dimensional package structure and raise of heat flow density.

In order to increase heat dissipation efficiency in the package structures, multiple package structures with a heat sink have been developed, for example HSBGA (Heat Slug Ball Grid Array), which transfer heat to the outer space of the package structure by using a heat sink with high heat transfer coefficient.

FIG. 1 shows a conventional HSBGA package structure, which has a substrate 10 with a chip 20 set thereon and includes a heat sink 30 attached on the substrate by using an adhesive, and a package resin 40 covering the chip 20 and the heat sink 30. As shown in the figure, the heat sink 30 includes an external portion 32 and an internal portion 34, wherein the internal portion 34 is attached onto the substrate 10 and the external portion 32 is exposed to the package resin 40. However, during the process of attaching the heat sink 30 to the substrate 10, the heat sink 30 deviates from the predetermined position before curing due to vibration caused by the fabrication equipment or improper operation, and results in decrease of yield rate.

### SUMMARY OF THE INVENTION

To solve the above-mentioned problem, one objective of the present invention is to provide a semiconductor package structure with a heat sink, which prevents the deviation of the heat sink during the attaching process and increases yield rate of the package. In addition, the semiconductor package structure improves the heat dissipation efficiency and reduces the warpage issue of the package after packaging by utilizing support portions of the heat sink.

To achieve the above-mentioned objective, a semiconductor package structure with a heat sink according to one embodiment of the present invention includes a substrate having a chip mounting area and a plurality of through holes surrounding the chip mounting area; a chip set on the chip mounting area and electrically connected to the substrate; a heat sink covering the chip, wherein the heat sink has a plurality of support portions extending from the upper surface to the lower surface of the substrate via those through holes; and a molding compound covering the chip, a portion of the substrate and the heat sink.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

FIG. 1 is a cross-section diagram showing a conventional HSBGA package structure.

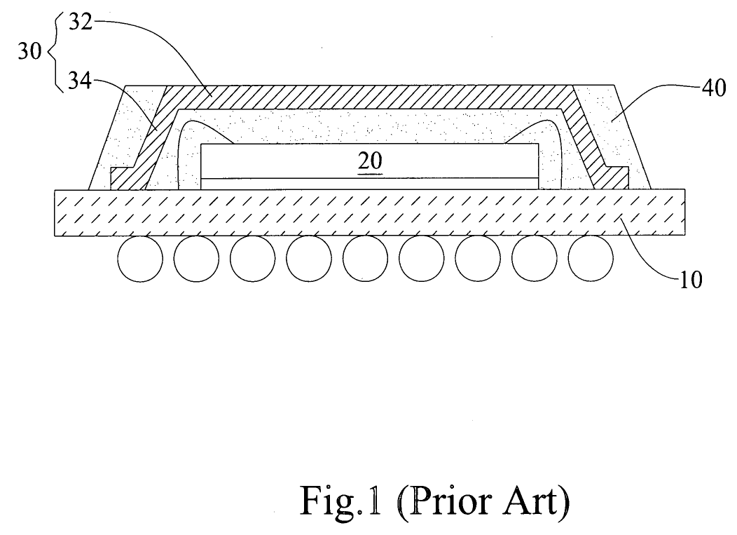

FIG. 2 is a cross-section diagram showing a semiconductor package structure with a heat sink according to one embodiment of the present invention.

FIG. 3A is a cross-section diagram showing a semiconductor package structure with a heat sink according to another embodiment of the present invention.

FIG. 3B is a top view of FIG. 3A according to one embodiment.

FIG. 4A is a cross-section diagram showing a semiconductor package structure with a heat sink according to yet another embodiment of the present invention.

FIG. 4B is a cross-section diagram showing a semiconductor package structure with a heat sink having another protrusion according to one embodiment of the present invention.

### DESCRIPTION OF THE PREFERRED EMBODIMENT

The following descriptions of specific embodiments of the present invention have been presented for purposes of illustrations and description and are not intended to be exclusive or to limit the invention to the precise forms disclosed

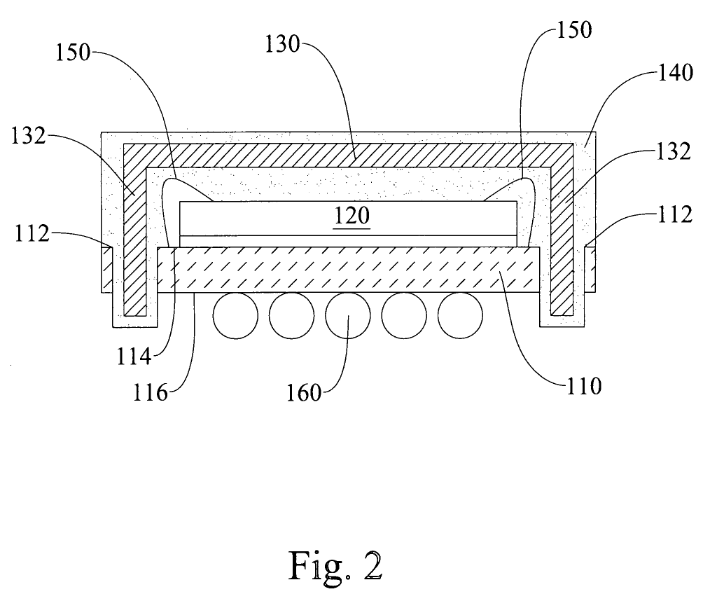

First of all, refer to FIG. 2 which is a cross-section diagram showing a semiconductor package structure with a heat sink according to one embodiment of the present invention. As shown in the figure, a semiconductor package structure with a heat sink includes a substrate 110 having a chip mounting area (not shown) and a plurality of through holes 112 surrounding the chip mounting area. For example, the chip mounting area is a specific area of an upper surface 114 on the substrate 110. A chip 120 is set on the chip mounting area and electrically connected to the substrate 110. In the embodiment, the chip 120 is connected to the substrate 110 with a plurality of leads 150 as shown in the figure; it should be understood that the method for electrically connecting the chip 120 with the substrate 110 is not limited to wire bonding method, but other methods, e.g. flip chip method, may be practiced in the structure of the present invention. A heat sink 130 covers the chip 120, wherein the heat sink 130 has a plurality of support portions 132 extending from the upper surface 114 to a lower surface 116 of the substrate 110 via those through holes 112. A molding compound 140 covers the chip 120, a portion of the substrate 110 and the heat sink 130.

Following the above description, in one embodiment, the semiconductor package structure further includes a plurality of bumps 160 arranged on the lower surface 116 of the substrate 110 and electrically connecting the semiconductor package structure to other external devices. Further, the support portions 132 on the heat sink 130 may have a stripe shape and be inserted into the through holes 112 on the substrate 110 with ease. In one embodiment, the number of the through holes 112 on the substrate 110 exceeds the number of the support portions 132 on the heat sink 130. That is, in case of the number of the through holes 112 equaling to the number of the support portions 132, after the support portions 132 having a strip shape pass through the through holes 112, the molding compound 140 used for molding passes through the through holes 112 and covers the support portions 132 protruding from the substrate 110; otherwise, in case of the number of the through holes 112 exceeding the number of the support portions 132, some of the molding compound 140 may flow through the through holes 112 directly to form the support bumps which may prevent the disintegration caused by non-uniform applied force while the semiconductor package structure is packaged into other external devices or warpage occurred during the molding compound cures.

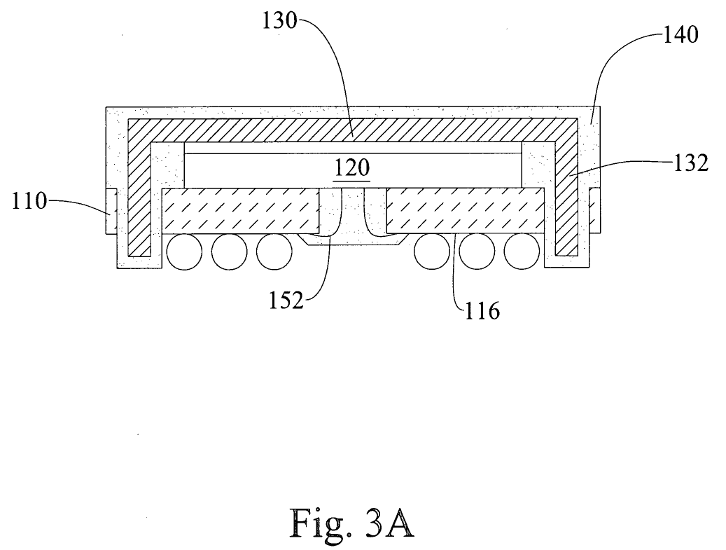

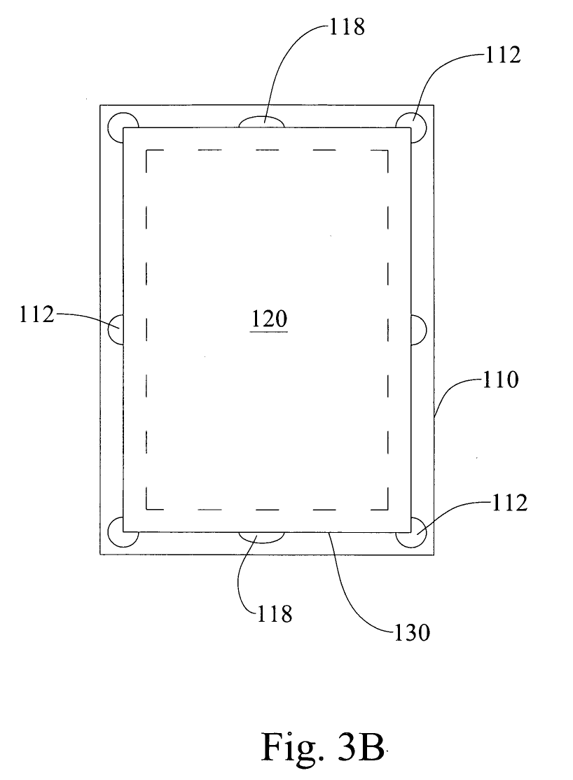

Next referring to FIG. 3A, in another preferred embodiment, a window 118 (as shown in FIG. 3B) is further configured at the chip mounting area on the substrate 110 for the need of window-type semiconductor package. As shown in the figure, a plurality of leads 152 pass through the windows 118 and electrically connect the chip 120 with the lower surface 116 of the substrate 110. In addition, in order to shrink the thickness of the package and enhance the heat dissipation rate, the heat sink 130 may directly attach to the chip 120 by using a thermally conductive dielectric adhesive, and the attaching also assists the positioning of the heat sink 130. In another embodiment, the heat sink 130 partially emerges from the molding compound 140. Furthermore, refer to FIG. 3B which is a possible top view of FIG. 3A. It should be understood that the position and shape of the through holes 112 is not limited thereon.

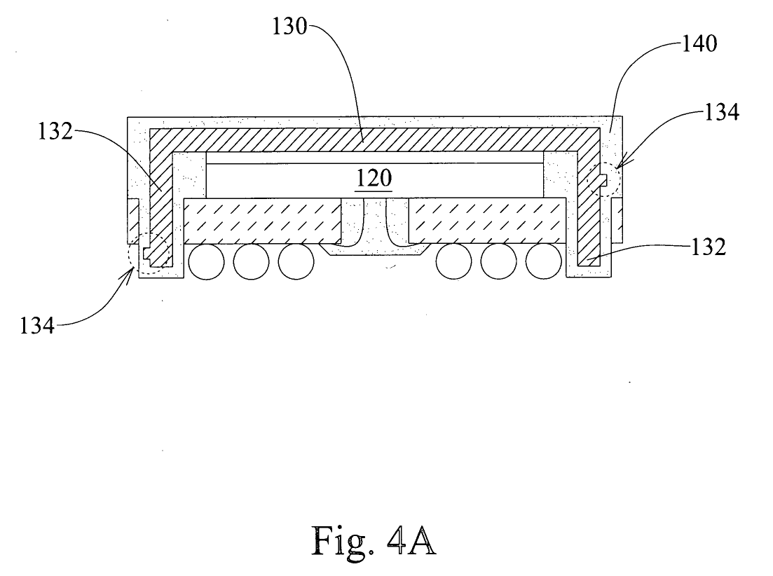

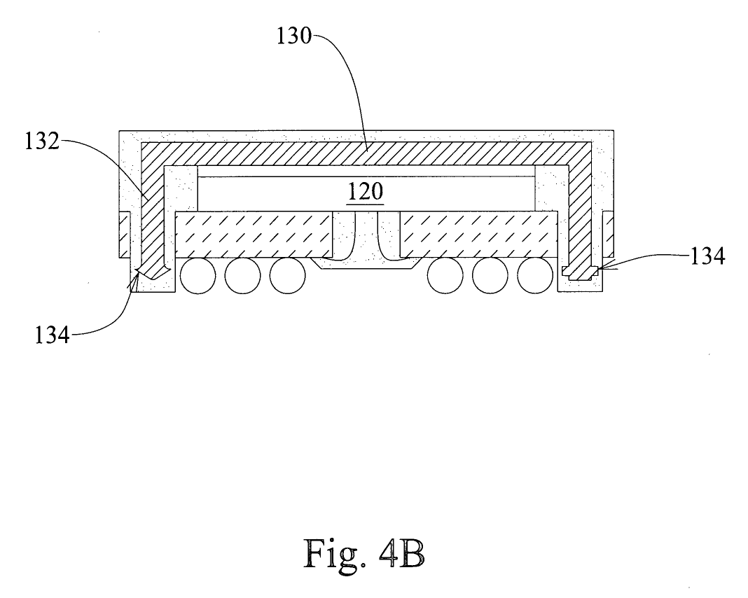

Following the above description, referring to FIG. 4A, in one embodiment, the semiconductor package structure further includes at least one protrusion 134 protruding from the support portion 132, wherein the protrusion 134 may form an angle, e.g. an acute angle, an obtuse angle, or a right angle (as shown in the figure), with the support portion 132 to increase the conjunction and friction force between the molding compound 140 and the heat sink 130 to prevent the possible disintegration of the heat sink 130. The protrusion 134 has no shape limitation: for example, the structure of the protrusion 134 of a semiconductor package structure according to another embodiment is depicted in FIG. 4B, but the shape of the protrusion 134 is not thus limited. In yet another embodiment, a coarse surface is formed at the contact surface between the heat sink 130 and the molding compound 140 by surface processing to increase the friction force between the molding compound 140 and the heat sink 130 thereafter.

According to the above descriptions, one characteristic of the present invention is to utilize support portions of the heat sink which pass through the substrate to increase the heat dissipation area and improve the warpage issues occurred during or after the packaging process, wherein the shape and number of the support portions is not limited. Besides, the support portions protrudes from the lower surface of the substrate, and the support portions of the heat sink covered with the molding compound after packaging may also provide support for the package structure. The semiconductor package structure with a heat sink of the present invention may reduce the disintegration problem of the package possibly occurred when the package is packaged into external devices. In addition, the support portions of the heat sink may further include a protrusion or a coarse surface formed at the contact surface between the molding compound and the heat sink to increase the conjunction strength between the molding compound and the heat sink. Besides, the protrusion has no shape and size limit so that the manufacturing process of the package is more flexible.

To sum up the foregoing descriptions, the present invention provides a semiconductor package structure with a heat sink, which prevents the deviation of the heat sink during the attaching process and increase yield rate of the package. In addition, the semiconductor package structure improves the heat dissipation efficiency and reduces the warpage issue of the package after packaging by utilizing the support portions of the heat sink.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A semiconductor package structure with a heat sink comprising:
a substrate having a chip mounting area and a plurality of through holes surrounding the chip mounting area;
a chip set on the chip mounting area and electrically connected to the substrate;
a heat sink covering the chip, wherein the heat sink has a plurality of support portions extending from the upper surface to the lower surface of the substrate via the through holes; and
a molding compound covering the chip, a portion of the substrate and the heat sink.

2. A semiconductor package structure with a heat sink according to claim 1, wherein the number of the through holes on the substrate exceeds or equals to the number of the support portions on the heat sink.

3. A semiconductor package structure with a heat sink according to claim 1, wherein a window is further configured at the chip mounting area on the substrate.

4. A semiconductor package structure with a heat sink according to claim 3, wherein a plurality of leads pass through the window and electrically connect the chip with the lower surface of the substrate.

5. A semiconductor package structure with a heat sink according to claim 1, further comprising at least one protrusion protruding from the support portion, wherein the protrusion may form an angle with the support portion.

6. A semiconductor package structure with a heat sink according to claim 1, further comprising a coarse surface formed at the surface of the heat sink.

7. A semiconductor package structure with a heat sink according to claim 1, further comprising a plurality of bumps arranged on the lower surface of the substrate.
